(19) United States
(12) Patent Application Publication
(10) Pub. No.: US 2023/0094023 A1
(43) Pub. Date: Mar. 30, 2023

(54) CHARGED PARTICLE BEAM IMAGE PROCESSING DEVICE AND CHARGED PARTICLE BEAM APPARATUS INCLUDING THE SAME

(71) Applicant: Hitachi High-Tech Corporation, Tokyo (JP)

(72) Inventors: Keiichiro HITOMI, Tokyo (JP); Takahiro KAWASAKI, Tokyo (JP)

(73) Assignee: Hitachi High-Tech Corporation, Tokyo (JP)

(21) Appl. No.: 17/954,050

(22) Filed: Sep. 27, 2022

(30) Foreign Application Priority Data
Sep. 30, 2021 (JP) 2021-161350

(51) Int. Cl. G06T 7/00; G06T 7/13; G06T 7/11; G01N 23/2251

(52) U.S. Cl. CPC G06T 7/0004; G06T 7/13; G06T 7/11; G01N 23/2251; G06T 2207/10061; G06T 2207/30148; G06T 2207/20021; G06T 2207/20072

(57) ABSTRACT

To provide a charged particle beam image processing device in which a proper inspection region for an observation image that includes an edge of a line pattern can be set.

A charged particle beam image processing device performs image processing on an observation image generated by a charged particle beam apparatus, the charged particle beam image processing device includes: an extraction unit configured to extract an edge of a line pattern from an inspection region of the observation image; a division unit configured to divide the inspection region into sections each having a plurality of measurement points; a measurement unit configured to measure a line edge roughness in each of the sections and generate distribution data of the line edge roughness in each section; a calculation unit configured to calculate a line edge roughness in the entire inspection region and calculate a theoretical curve of the line edge roughness in each section; and a determination unit configured to determine whether the inspection region is proper based on a comparison between the distribution data and the theoretical curve.

### CLAIM OF PRIORITY

The present application claims priority from Japanese Patent Application JP 2021-161350 filed on Sep. 30, 2021, the content of which is hereby incorporated by reference into this application.

### TECHNICAL FIELD

The present invention relates to a charged particle beam image processing device for performing image processing on an observation image generated by a charged particle beam apparatus used for a line pattern inspection of a semiconductor.

### BACKGROUND ART

The charged particle beam apparatus is an apparatus that generates an observation image for observing a fine structure of a sample by irradiating the sample with a charged particle beam such as an electron beam, and is used for a process of manufacturing a semiconductor, or the like. In the process of manufacturing a semiconductor, it is important to measure a line edge roughness (LER) which is unevenness on an edge of a line pattern of the semiconductor.

PTL 1 discloses that a fluctuation in LER is measured based on a theoretical basis. Specifically, PTL 1 discloses that a spatial frequency distribution of LERs of edges at a plurality of positions measured in a measurement region shorter than an inspection region of an observation image of a line pattern is calculated, and LER of the inspection region is calculated based on the calculated spatial frequency distribution.

### CITATION LIST

### Patent Literature

PTL 1: JP-A-2008-116472

### SUMMARY OF INVENTION

### Technical Problem

However, only periodicity of an edge group is evaluated, and continuity of the edge group is not evaluated in PTL 1. That is, when an interval between edges in the edge group is sparse due to the inspection region that is too wide, the continuity of the edge group cannot be kept, and measurement accuracy of the line edge roughness is reduced.

Accordingly, an object of the invention is to provide a charged particle beam image processing device in which a proper inspection region for an observation image that includes an edge of a line pattern can be set.

### Solution to Problem

In order to achieve the above object, the invention provides a charged particle beam image processing device for performing image processing on an observation image generated by a charged particle beam apparatus, and the charged particle beam image processing device includes: an extraction unit configured to extract an edge of a line pattern from an inspection region of the observation image; a division unit configured to divide the inspection region into sections each having a plurality of measurement points; a measurement unit configured to measure a line edge roughness in each of the sections and generate distribution data of the line edge roughness in each section; a calculation unit configured to calculate a line edge roughness in the entire inspection region and calculate a theoretical curve of the line edge roughness in each section; and a determination unit configured to determine whether the inspection region is proper based on a comparison between the distribution data and the theoretical curve.

### Advantageous Effects of Invention

According to the invention, it is possible to provide a charged particle beam image processing device in which a proper inspection region for an observation image that includes an edge of a line pattern can be set.

### BRIEF DESCRIPTION OF DRAWINGS

FIG. 1 is a diagram illustrating an example of an overall configuration of a charged particle beam image processing device according to Embodiment 1.

FIG. 2 is a diagram illustrating an example of an overall configuration of a charged particle beam apparatus.

FIG. 3 shows diagrams illustrating a proper inspection region and a sampling interval.

FIG. 4 is a diagram illustrating an example of a flow of processing according to Embodiment 1.

FIG. 5 is a graph illustrating a comparison between distribution data and a theoretical curve.

FIG. 6 shows diagrams illustrating an example of a warning screen for warning that the sampling interval is not proper.

### DESCRIPTION OF EMBODIMENTS

Hereinafter, an embodiment of a charged particle beam image processing device according to the invention will be described with reference to accompanying drawings. In the following description and the accompanying drawings, components having the same function and structure are denoted by the same reference numerals, and repeated description thereof will be omitted.

### Embodiment 1

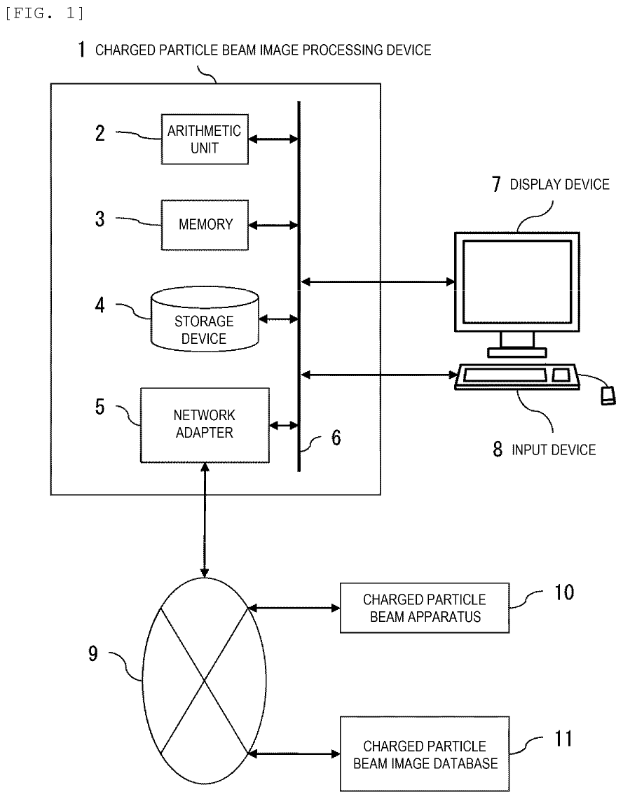

FIG. 1 is a diagram illustrating a hardware configuration of a charged particle beam image processing device 1. The charged particle beam image processing device 1 is configured by connecting an arithmetic unit 2, a memory 3, a storage device 4, and a network adapter 5 to one another in a manner of being capable of transmitting and receiving signals via a system bus 6. The charged particle beam image processing device 1 is connected to a charged particle beam apparatus 10 and a charged particle beam image database 11 via a network 9 in a manner of being capable of transmitting and receiving signals. A display device 7 and an input device 8 are connected to the charged particle beam image processing device 1. Here, the description “capable of transmitting and receiving signals” means a state that signals can be received and transmitted mutually or from one to another regardless of electrically, optically, by wire or wirelessly.

The arithmetic unit 2 is a device that controls operations of components, and specifically is a central processing unit (CPU), a micro processor unit (MPU), or the like. The arithmetic unit 2 loads a program and data necessary for executing the program that are stored in the storage device 4, into the memory 3 and executes the program, so as to perform various types of image processing on a charged particle beam image. The memory 3 stores the program executed by the arithmetic unit 2 and a progress of arithmetic processing. The storage device 4 stores the program executed by the arithmetic unit 2 and the data necessary for executing the program, and is specifically a hard disk drive (HHD), a solid state drive (SSD), or the like. The network adapter 5 is used for connecting the charged particle beam image processing device 1 to the network 9 such as an LAN, a telephone line, or the Internet. Various type of data processed by the arithmetic unit 2 may be transmitted to and received from the outside of the charged particle beam image processing device 1 via the network 9 such as a local area network (LAN).

The display device 7 is a device that displays a processing result or the like of the charged particle beam image processing device 1, and is specifically a liquid crystal display, a touch panel, or the like. The input device 8 is an operation device with which an operator gives an operation instruction to the charged particle beam image processing device 1, and is specifically a keyboard, a mouse, a touch panel, or the like. The mouse may be another pointing device such as a trackpad or trackball.

The charged particle beam apparatus 10 is a device that generates an observation image for observing a sample by irradiating the sample with a charged particle beam, and is, for example, a scanning electron microscope (SEM) that generates an observation image by scanning the sample with an electron beam. The charged particle beam image database 11 is a database system that stores an observation image generated by the charged particle beam apparatus 10, a corrected image obtained by performing image processing on the observation image, and the like.

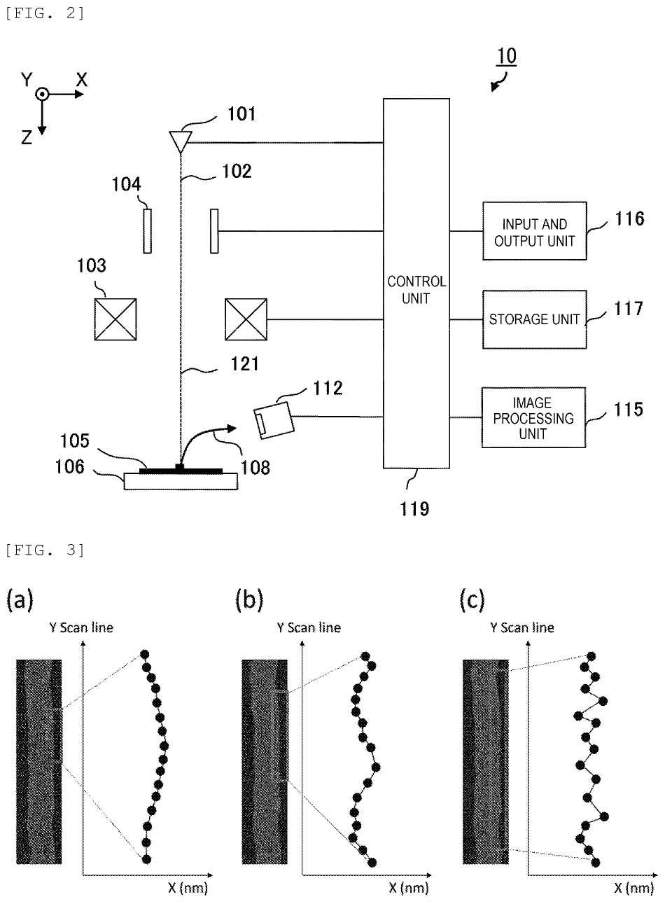

An overall configuration of the scanning electron microscope, which is an example of the charged particle beam apparatus 10, will be described with reference to FIG. 2. In FIG. 2, a direction perpendicular to a paper surface is referred to as an X axis, a vertical direction is referred to as a Y axis, and a horizontal direction is referred to as a Z axis. The scanning electron microscope includes an electron beam source 101, an objective lens 103, a deflector 104, a movable stage 106, a detector 112, an image processing unit 115, an input and output unit 116, a storage unit 117, and a control unit 119. The units will be described below.

The electron beam source 101 is a beam source that irradiates a sample 105 with a primary electron beam 102 accelerated by a predetermined acceleration voltage.

The objective lens 103 is a focusing lens for focusing the primary electron beam 102 on a surface of the sample 105. In many cases, a magnetic pole lens including a coil and a magnetic pole is used as the objective lens 103.

The deflector 104 is a coil or an electrode that generates a magnetic field or an electric field for deflecting the primary electron beam 102. By deflecting the primary electron beam 102, the surface of the sample 105 is scanned with the primary electron beam 102. A straight line that connects the electron beam source 101 and a center of the objective lens 103 is referred to as an optical axis 121, and the primary electron beam 102 not deflected by the deflector 104 is emitted to the sample 105 along the optical axis 121.

The movable stage 106 holds the sample 105 and moves the sample 105 in an X direction and a Y direction.

The detector 112 is a detector that detects a secondary electron 108 emitted from the sample 105 irradiated with the primary electron beam 102. An E-T detector including a scintillator, a light guide, and a photomultiplier tube or a semiconductor detector can be used as the detector 112. A detection signal output from the detector 112 is transmitted to the image processing unit 115 via the control unit 119.

The image processing unit 115 is an arithmetic unit that generates an observation image based on the detection signal output from the detector 112, and is, for example, a micro processing unit (MPU) or a graphics processing unit (GPU). The image processing unit 115 may perform various types of image processing on the generated observation image. The charged particle beam image processing device 1 described with reference to FIG. 1 may be the image processing unit 115.

The input and output unit 116 is a device that inputs an observation condition for observing the sample 105 and displays an image generated by the image processing unit 115, and is, for example, a keyboard or a mouse, a touch panel, or a liquid crystal display.

The storage unit 117 is a device in which various type of data and programs are stored, and is, for example, a hard disk drive (HDD) or a solid state drive (SSD). The storage unit 117 stores a program executed by the control unit 119 or the like, an observation condition input from the input and output unit 116, an image generated by the image processing unit 115, and the like.

The control unit 119 is an arithmetic unit that controls the units and processes and transmits data generated by the units, and is, for example, a central processing unit (CPU) or an MPU.

An observation image for observing a line pattern of a semiconductor is generated by the charged particle beam apparatus described above, and a line edge roughness (LER), which is unevenness of an edge of a line pattern, is measured by using the observation image. In order to measure the line edge roughness with high accuracy, it is important to set a proper inspection region for the observation image.

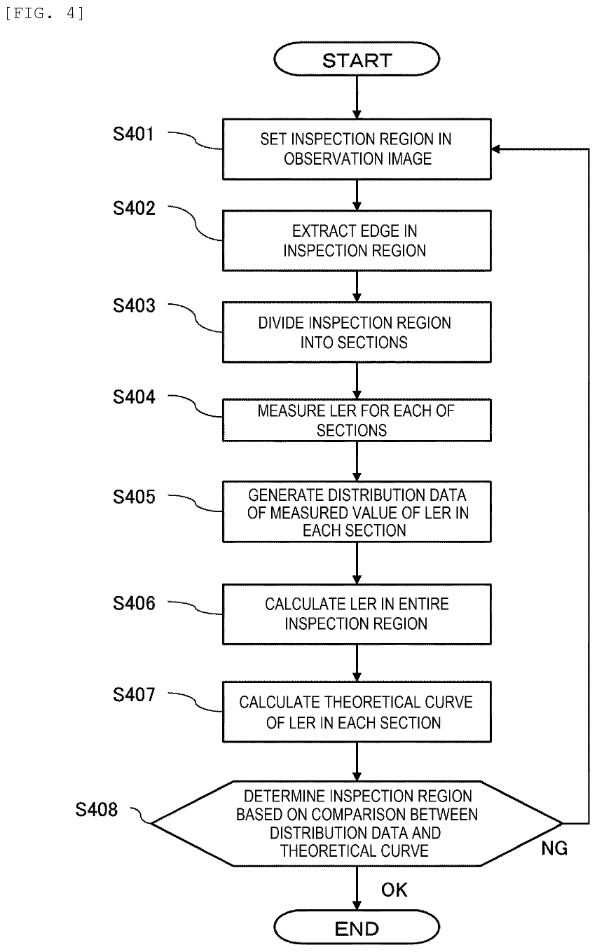

The proper inspection region will be described with reference to FIG. 3. (a), (b), and (c) of FIG. 3 illustrate cases where a size of the inspection region set for the observation image is small, medium, and large. The inspection region is shown by a vertically long rectangle in each of (a), (b), and (c) of FIG. 3. A position of the edge extracted in the inspection region is shown by a line graph in each of (a), (b), and (c) of FIG. 3.

As shown in (a) of FIG. 3, when the inspection region is relatively small, a sampling interval of the extracted edge is dense, so that continuity of an edge group can be kept, but an evaluation on periodicity of the edge group is insufficient. In addition, when the inspection region is relatively large as shown in (c) of FIG. 3, the sampling interval of the extracted edge is sparse, so that the periodicity of the edge group can be evaluated, but the continuity of the edge group cannot be kept. Therefore, it is necessary to set a proper inspection region in which the periodicity of the edge group can be evaluated while keeping the continuity of the edge group, as shown in (b) of FIG. 3. In Embodiment 1, a proper inspection region is set by a flow of processing to be described below.

An example of the flow of the processing according to Embodiment 1 will be described for each step with reference to FIG. 4.

### (S401)

The inspection region is set for the observation image generated by the charged particle beam apparatus 10. The inspection region may be set by the arithmetic unit 2, and may be set by an operator using the input device 8. The arithmetic unit 2 sets the sampling interval of the edge according to the set inspection region.

### (S402)

The arithmetic unit 2 extracts an edge of a line pattern in the inspection region set in S401. For example, in a profile which is a set of luminance values arranged in a horizontal direction of the inspection region, a position at which a difference between adjacent luminance values is maximum is extracted as an edge. The edge is extracted at the sampling interval set in the inspection region.

### (S403)

The arithmetic unit 2 divides the inspection region set in S401 into a plurality of sections. The sections obtained by division each have a plurality of measurement points.

### (S404)

The arithmetic unit 2 measures the line edge roughness in each of the sections obtained by division in S403. The line edge roughness is expressed by the following equation as a standard deviation σ of a distance from a reference line to each edge, for example. The reference line is an approximate straight line calculated based on the edge group in the entire inspection region, or a straight line set in the vertical direction in the observation image.

$$σ = \frac{1}{k} \sqrt{{\sum }_{i = 1}^{k} {( {x}_{i} - {x}_{k \_ ave} )}^{2}} \qquad [ Math 1 ]$$

Here, k is the number of measurement points in the section, i is an integer from 1 to k, xᵢ is the distance from the reference line to each edge, and x_{k_ave} is an average value of xᵢ in each section.

### (S405)

The arithmetic unit 2 generates distribution data of the line edge roughness for each section measured in S404. The distribution data is generated as a histogram in which, for example, a horizontal axis represents a range of the line edge roughness and a vertical axis represents a frequency in each range.

### (S406)

The arithmetic unit 2 calculates the line edge roughness in the entire inspection region set in S401. The line edge roughness σₜᵣᵤₑ in the entire inspection region is calculated by, for example, the following equation.

$${σ}_{t r u e} = \frac{1}{n} \sqrt{{\sum }_{i = 1}^{n} {( {x}_{i} - {x}_{a v e} )}^{2}} \qquad [ Math 2 ]$$

Here, n is the number of edges in the entire inspection region, i is an integer from 1 to n, xᵢ is the distance from the reference line to each edge, and xₐᵥₑ is an average value of xᵢ.

### (S407)

The arithmetic unit 2 calculates a theoretical curve of the line edge roughness for each section measured in S404. The theoretical curve is calculated by the following equation as a probability density f (σ; k) of the line edge roughness σ for each section having, for example, k measurement points.

$$f ( σ ; k ) = \frac{1}{{2}^{\frac{k}{2}} Γ ( \frac{k}{2} )} {( \frac{k {σ}^{2}}{{σ}_{true}} )}^{( \frac{k}{2} - 1 )} {e}^{- \frac{k {σ}^{2}}{2 {σ}_{true}}} \qquad [ Math 3 ]$$

Here, Γ(k/2) is a gamma function expressed by the following equation.

$$Γ ( \frac{k}{2} ) = {\int }_{0}^{∞} {t}^{( \frac{k}{2} - 1 )} {e}^{- t} dt \qquad [ Math 4 ]$$

### (S408)

The arithmetic unit 2 determines whether the inspection region set in S401 is proper based on a comparison between the distribution data generated in S405 and the theoretical curve calculated in S407. When the inspection region is proper, the flow of the processing ends, and when the inspection region is not proper, the processing returns to S401 and the inspection region is set again.

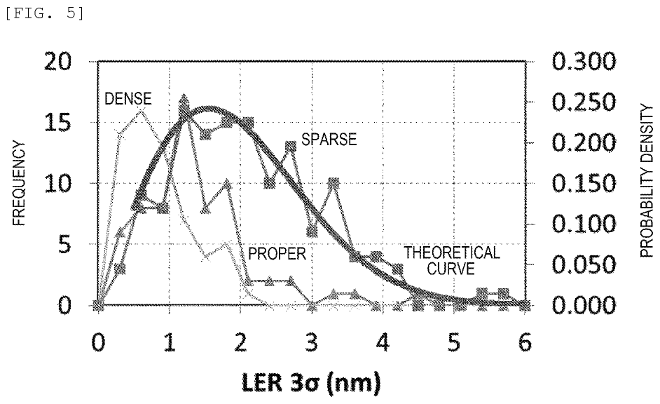

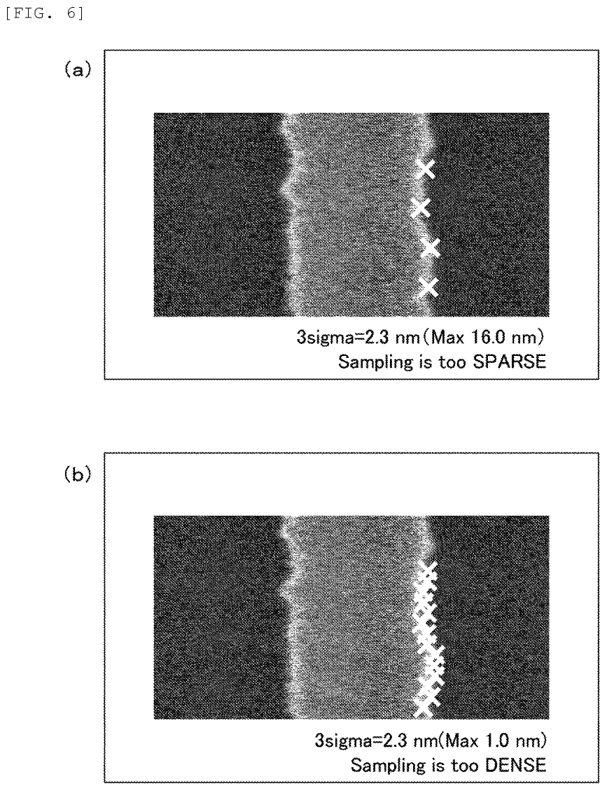

The comparison between the distribution data and the theoretical curve will be described with reference to FIG. 5. FIG. 5 shows a theoretical curve and three histograms which are distribution data generated in respective inspection regions shown in FIG. 3. In FIG. 5, the horizontal axis is 3σ, which is the line edge roughness for each section having k measurement points, the vertical axis of the distribution data is a frequency on a left side, and the vertical axis of the theoretical curve is a probability density on a right side.

The distribution data in which the sampling interval is sparse and the continuity of the edge group cannot be kept, includes a relatively large line edge roughness of 3σ >5 nm. The distribution data in which the sampling interval is dense and the evaluation on periodicity is insufficient, includes only a relatively small line edge roughness of 3σ <2.5 nm. That is, when a maximum value of the line edge roughness of the distribution data is within a predetermined range, for example, between an upper limit value and a lower limit value obtained based on the theoretical curve, it can be determined that the inspection region is proper. When the maximum value of the line edge roughness of the distribution data is equal to or larger than the upper limit value, it can be determined that the sampling interval is sparse and the inspection region is too wide, and when the maximum value of the line edge roughness of the distribution data is equal to or less than the lower limit value, it can be determined that the sampling interval is dense and the inspection region is too narrow.

The upper limit value and the lower limit value may be set based on an area surrounded by the theoretical curve and the horizontal axis. When the theoretical curve is calculated as the probability density f (σ; k), the area surrounded by the theoretical curve and the horizontal axis, that is, a value obtained by integrating the probability density f (σ; k) from σ=0 to σ=∞ is 1. Therefore, the line edge roughness at which the area surrounded by the theoretical curve and the horizontal axis is, for example, 0.99 is set as the upper limit value, and the line edge roughness at which the area is 0.5 is set as the lower limit value.

The determination in S408 is not limited to the use of the maximum value of the line edge roughness in the distribution data. For example, when a correlation coefficient between the distribution data and the theoretical curve is within a predetermined range, it may be determined that the inspection region is proper. Prior to calculating the correlation coefficient between the distribution data and the theoretical curve, normalization is performed such that the entire area of the histogram, which is the distribution data, is 1. That is, the correlation coefficient between the normalized data, which is obtained by normalizing the distribution data, and the theoretical curve is calculated, and when the calculated correlation coefficient is within a predetermined range, it is determined that the inspection region is proper.

When it is determined in S408 that the inspection region is not proper, a warning screen shown in FIG. 6 may be displayed on the display device 7. (a) of FIG. 6 is a warning screen when the sampling interval is sparse and (b) of FIG. 6 is a warning screen when the sampling interval is dense, and the extracted edges are indicated by x marks. By displaying whether the sampling interval is sparse or dense, the operator can properly perform resetting of the inspection region.

According to the flow of the processing described above, it is determined whether the inspection region set for the observation image including the edge of the line pattern is proper, and when the inspection region is not proper, the inspection region is reset. That is, according to Embodiment 1, it is possible to provide a charged particle beam image processing device in which a proper inspection region can be set.

The embodiment of the invention has been described above. The invention is not limited to the embodiment above, and can be embodied by modifying components without departing from a spirit of the invention. In addition, a plurality of components disclosed in the above embodiment may be appropriately combined. Further, some components may be deleted from all the components shown in the above embodiment.

### REFERENCE SIGNS LIST

1 charged particle beam image processing device
2 arithmetic unit
3 memory
4 storage device
5 network adapter
6 system bus
7 display device
8 input device
10 charged particle beam apparatus
11 charged particle beam image database
101 electron beam source
102 primary electron beam
103 objective lens
104 deflector
105 sample
106 movable stage
108 secondary electron
112 detector
115 image processing unit
116 input and output unit
117 storage unit
119 control unit
121 optical axis

1. A charged particle beam image processing device for performing image processing on an observation image generated by a charged particle beam apparatus, comprising:
an extraction unit configured to extract an edge of a line pattern from an inspection region of the observation image;
a division unit configured to divide the inspection region into sections each having a plurality of measurement points;
a measurement unit configured to measure a line edge roughness in each of the sections and generate distribution data of the line edge roughness in each section;
a calculation unit configured to calculate a line edge roughness in the entire inspection region and calculate a theoretical curve of the line edge roughness in each section; and
a determination unit configured to determine whether the inspection region is proper based on a comparison between the distribution data and the theoretical curve.

2. The charged particle beam image processing device according to claim 1, wherein
when a maximum value of the line edge roughness in the distribution data is between an upper limit value and a lower limit value obtained based on the theoretical curve, the determination unit determines that the inspection region is proper.

3. The charged particle beam image processing device according to claim 1, wherein
when a correlation coefficient between normalized data, which is normalized such that an area of the distribution data is 1, and the theoretical curve is within a predetermined range, the determination unit determines that the inspection region is proper.

4. The charged particle beam image processing device according to claim 1, wherein
the calculation unit calculates the theoretical curve based on the line edge roughness in the entire inspection region and the measurement points.

5. The charged particle beam image processing device according to claim 1, further comprising:
a display unit configured to display whether a sampling interval is sparse or dense when the inspection region is determined not to be proper.

6. A charged particle beam apparatus, comprising:
the charged particle beam image processing device according to claim 1.
